(19) United States
(12) Patent Application Publication
(10) Pub. No.: US 2003/0235789 A1
(43) Pub. Date: Dec. 25, 2003

(54) Photolithography process for Mask ROM coding

(75) Inventor: Ching-Yu Chang, Yilan Hsien (TW)

Correspondence Address: J C PATENTS, INC., 4 VENTURE, SUITE 250, IRVINE, CA, 92618, US

(73) Assignee: MACRONIX INTERNATIONAL CO., LTD., HSINCHU (TW)

(21) Appl. No.: 10/065,711

(22) Filed: Nov. 12, 2002

(30) Foreign Application Priority Data
Jun. 25, 2002 (TW) 91113838

(51) Int. Cl. G03F 7/16; G03F 7/20; G03F 7/40

(52) U.S. Cl. 430/312; 430/319; 430/315; 430/330

(57) ABSTRACT

A photolithography process for Mask ROM coding is described. A substrate is provided having a memory array thereon. A first photoresist layer is formed on the substrate with first line/pace patterns, which include trenches having different lengths. A second photoresist layer is formed on the substrate with second line/pace patterns. The second line/space patterns comprise a plurality of linear patterns and linear spaces that are arranged regularly, and have an orientation different from that of the first line/space pattern. Consequently, a plurality of uniform coding windows are defined by the first line/space patterns and the second line/space patterns.

### CROSS REFERENCE TO RELATED APPLICATIONS

This application claims the priority benefit of Taiwan application serial no. 91113838, filed on Jun. 25, 2002.

### BACKGROUND OF INVENTION

1. Field of Invention

The present invention relates to a photolithography process. More particularly, the present invention relates to a photolithography process used in a coding process of a mask programmable read-only memory (Mask ROM).

2. Description of Related Art

A Mask ROM generally comprises a substrate, a plurality of buried bit lines in the substrate and a plurality of word lines crossing over the buried bit lines, wherein the substrate under the word lines and between the buried bit lines serves as the channel regions of the memory cells. A method for programming a Mask ROM comprises implanting ions into the channel regions of selected memory cells to raise their threshold voltages, which is called a coding implantation. The data (0/1) stored in a memory cell is dependent on the presence/absence of implanted ions in the channel region.

In a conventional coding process of a Mask ROM, a photoresist layer is formed on the substrate and patterned to form coding windows over the channel regions of selected memory cells. An ion implantation is then performed using the photoresist layer as a mask to dope the selected channel regions. However, since the coding windows do not distribute evenly and there must be some regions with dense coding window patterns (dense regions) and some with isolated coding window patterns (sparse regions) on the coding photo mask, the critical dimensions (CD) of the coding windows are not uniform. It is because the optical proximity effect (OPE) for the dense regions is stronger than that for the isolated regions, and the light intensity through the dense regions therefore is different from that through the sparse regions. The CD deviation of coding windows will cause misalignments of the coding implantation, which may results in severe coding errors to lower the reliability of the Mask ROM product.

To prevent the deviation of critical dimensions over the sparse region and the dense region, quite a few methods are proposed based on the use of phase shift masks (PSM) or on optical proximity correction (OPC) techniques. The OPC method forms assistant patterns on the photo mask to compensate the CD deviation caused by the optical proximity effect (OPE). However, the two methods both need to design special patterns on the photo masks, so the fabrication of the photo masks are time-consuming, expensive and difficult. Moreover, it is not easy to debug the patterns on the photo mask after the fabrication of the photo mask is completed.

Furthermore, with a current photolithography process using an exposure light of 248 nm, the maximal resolution obtained is merely 0.16 μm, i.e., the patterns cannot be formed with a critical dimension smaller than 0.16 μm. Therefore, it is quite important to raise the resolution of the photolithography process beyond the above limitation to further miniaturize the devices.

### SUMMARY OF INVENTION

Accordingly, this invention provides a photolithography process used in a coding process of a Mask ROM to make the coding windows in the dense regions and those in the sparse regions have the same critical dimension.[0007] This invention also provides a photolithography process capable of preventing CD deviation and improving the resolution without using optical proximity correction (OPC) or phase shift masks (PSM).

A photolithography process for Mask ROM coding of this invention comprises the following steps. A substrate is provided having an array of memory cells thereon. A first photoresist layer is formed on the substrate covering the memory cells, and then a first exposure and development process is performed to define the first photoresist layer into first line/pace patterns that include a plurality of trenches having different lengths. A second photoresist layer is formed on the substrate covering the first photoresist layer, and then a second exposure and development process is performed to define the second photoresist layer into second line/pace patterns. The second line/space patterns comprise a plurality of linear patterns and linear spaces that are arranged regularly, and have an orientation different from or perpendicular to that of the first line/space patterns. A plurality of coding windows are thus defined by the first and the second line/space patterns. With the photolithography process, a coding window defined by the first and the second line/space patterns can have a rectangle shape or a square shape.

Another photolithography process of this invention comprises the following steps. A first photoresist layer is formed on a substrate, and then a first exposure and development process is performed to define the first photoresist layer into first line/pace patterns that include a plurality of trenches having different lengths. A second photoresist layer is formed on the substrate covering the first photoresist layer, and then a second exposure and development process is performed to define the second photoresist layer into second line/pace patterns. The second line/space patterns comprise a plurality of linear patterns and linear spaces that are arranged regularly, and have an orientation different from or perpendicular to that of the first line/space patterns, while a plurality of openings are defined by the first and the second line/space patterns. With the photolithography process, an opening defined by the first and the second line/space patterns may have a rectangle shape or a square shape.

As mentioned above, in the photolithography process for Mask ROM coding of this invention, the coding windows are defined by two set of line/space patterns that have different orientations. Since the CD deviation of line/space patterns is quite small, it is possible to prevent CD deviation of the coding windows in dense regions and in sparse regions without using OPC or PSM. Rectangle or square coding windows thus can be formed to precisely expose the entire channel regions predetermined to implant.

Moreover, by using the photolithography process of this invention, the critical dimensions of an opening can be reduced from 0.16 μm×0.16 μm to 0.12 μm×0.12 μm with a current exposure light of 248 nm without using OPC or PSM.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 schematically illustrates a top view of a Mask ROM;

FIG. 2A-2F schematically illustrate a coding process flow of the Mask ROM in FIG. 1 according to a preferred embodiment of this invention in a cross-sectional view along line I-I′;

FIG. 3 illustrates a top view of a photo mask used in the coding process of a Mask ROM according to the preferred embodiment of this invention;

FIG. 4 illustrates a top view of the first photoresist layer after the patterns on the photo mask in FIG. 3 are transferred onto it;

FIG. 5 illustrates a top view of the second patterned photoresist layer formed in the coding process of the Mask ROM according to the preferred embodiment of this invention; and

FIG. 6 illustrates the first patterned photoresist layer and the second patterned photoresist layer superimposed thereon in a top view.

### DETAILED DESCRIPTION

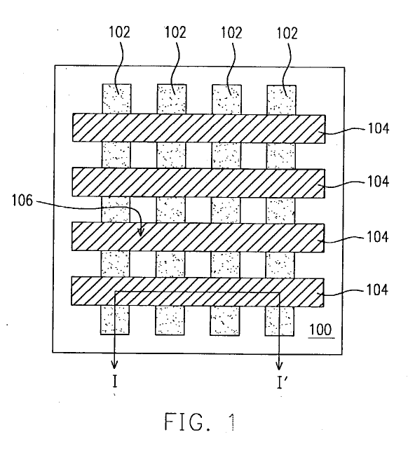

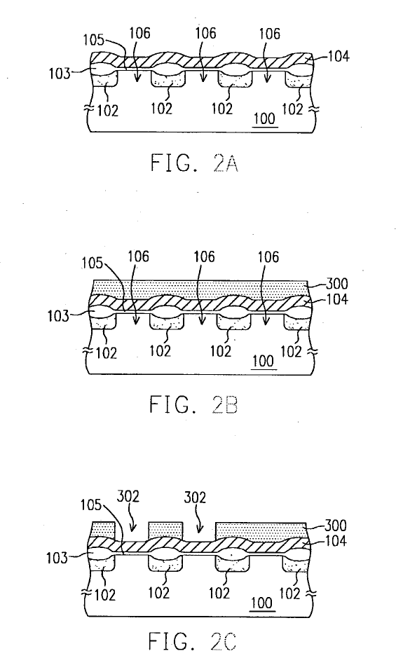

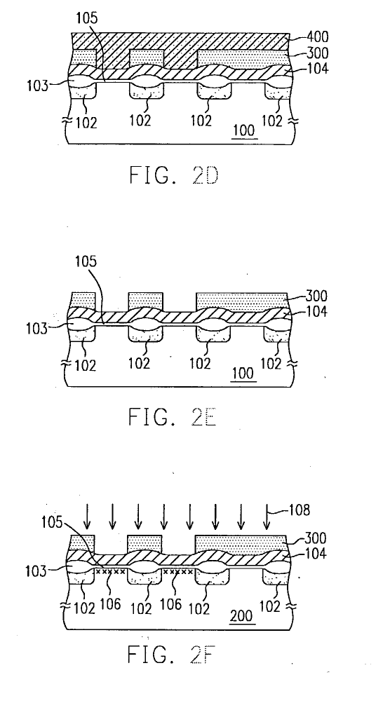

FIG. 1 schematically illustrates a top view of a Mask ROM, and FIG. 2A-2F schematically illustrate the coding process flow of the Mask ROM according to the preferred embodiment of this invention in a cross-sectional view along line I-I′.

Referring to FIG. 1 and 2A, the mask ROM comprises a substrate 100, a plurality of buried bit lines 102 in the substrate 100, and a plurality of word lines 104 that are isolated from the buried bit lines 102 by insulators 103. The word lines 104 comprise a material such as polysilicon. The substrate 100 under the word lines 104 and between the buried bit lines 102 serves as channels 106 of the memory cells.

Subsequently, a coding process is performed to program the Mask ROM with the steps described below.

Referring to FIG. 2B, the substrate 100 is coated with a photoresist layer 300, which may comprise negative photoresist or positive photoresist, but preferably comprises negative photoresist according to the present embodiment.

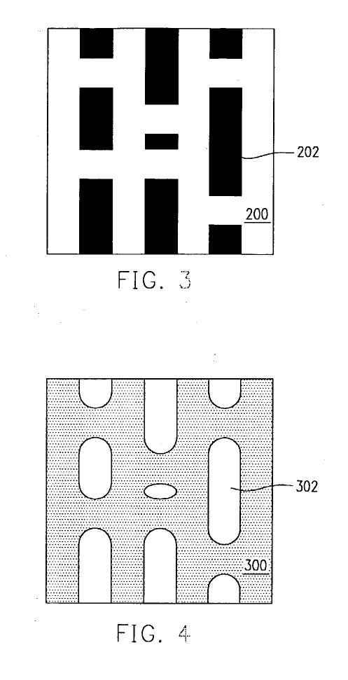

Referring to FIG. 2C and 4, a first exposure and development process is performed to pattern the photoresist layer 300 to form a plurality of openings 302 therein. The photo mask used in the first exposure process is illustrated in FIG. 3, having a plurality of first line/space patterns thereon. The first line/space patterns include a plurality of trench patterns 202 having different lengths, wherein the trench patterns 202 on the photo mask 200 approximately correspond to the channel regions predetermined to implant. Moreover, the first exposure process uses an exposure light with a wavelength such as 248 nm, and preferably uses off-axis illumination (OAI) to improve the resolution.

The first development process performed after the first exposure process is for developing the photoresist layer 300 to form the openings 302 therein, so as to complete the transfer of the first line/space patterns onto the photoresist layer 300. Since the photoresist layer 300 is of negative-type, the portions of the photoresist layer 300 corresponding to the transparent regions of the photo mask 200 still remain, and the portions corresponding to the opaque regions 202 on the photo mask 200 are removed to form the openings 302. Referring to FIG. 4, which illustrates a top view of the first photoresist layer after the patterns on the photo mask in FIG. 3 are transferred onto it. The openings 302 approximately cover the channel regions predetermined to implant.

Thereafter, the patterned photoresist layer 300 is hardened. If the photoresist layer 300 is of negative-type, the hardening method may comprise baking or ion implantation to increase the number of crosslinks in the negative photoresist layer 300. If the photoresist layer 300 is of positive-type, the hardening step can use ion implantation. Moreover, the baking step is conducted at 100-150° C. for 30-180 seconds, for example. The ion implantation step uses argon (Ar) ions or nitrogen (N₂) ions with an implanting energy of 2-50 KeV and a dosage of 1×10¹⁴ −3×10^{15 /cm}², for example.

Referring to FIG. 4 again, one feature of this invention is that the remaining portions of the photoresist layer 300 and the openings 302 approximately constitute line/space patterns. It is also noted that the corners of the openings 302 are rounded since the photolithography process does not apply optical proximity correction (OPC).

Referring to FIG. 2D, another photoresist layer 400 is formed on the substrate 100 covering the photoresist layer 300. The photoresist layer 400 may comprise positive photoresist or negative photoresist, but preferably comprises positive photoresist in the present embodiment.

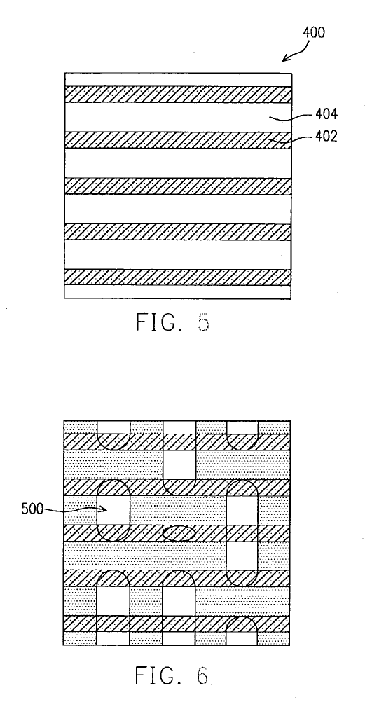

Referring to FIG. 2E and 5, a second exposure and development process is performed to pattern the photoresist layer 400 into second line/space patterns. The second line/space patterns comprise continuous linear spaces 404 and linear patterns 402 having a constant pitch/size, and have an orientation perpendicular to that of the first line/space patterns of the photoresist layer 300. In addition, the rounded corners of the openings 302 in the photoresist layer 300 are covered by the linear patterns 402 of the photoresist layer 400. The second exposure process uses an exposure light with a wavelength such as 248 nm, and preferably uses off-axis illumination (OAI) to improve the resolution.

FIG. 6 illustrates the first patterned photoresist layer and the second patterned photoresist layer superimposed thereon in a top view. Referring to FIG. 5 and 6, the linear patterns 402 of the photoresist layer 400 cover the rounded corners of the openings 302 in the photoresist layer 300 and divide each larger opening 302 into individual ones, so as to define a plurality of square coding windows 500. The square coding windows 500 correspond to the channel regions predetermined to implant and have uniform dimensions. Accordingly, this invention is capable of forming rectangle or square coding windows with uniform dimensions without using OPC or PSM. Moreover, since the coding windows are defined by two sets of line/space patterns that have different orientations and very small CD deviations, it is possible to prevent CD deviation of the coding windows over dense regions and sparse regions.

It is also noted that the resolution of a conventional photolithography process is merely 0.16 μm with an exposure light of 248 nm, while the resolution of this invention can be enhanced to about 0.12 μm with the same exposure light. Therefore, with two sets of line/space patterns, an opening can be formed with a square shape having dimensions of 0.12 μm×0.12 μm in this invention.

Referring to FIG. 2F and 6, an ion implantation 108 is performed using the patterned photoresist layers 300 and 400 as a mask to implant ions into the channel regions 106 under the square coding windows 500 to complete the coding process of the Mask ROM.

As mentioned above, in the photolithography process for Mask ROM coding of this invention, the coding windows are defined by two set of line/space patterns that have different orientations. Since the CD deviation of a line/space pattern is quite small, it is possible to prevent CD deviation of the coding windows over dense regions and sparse regions without using OPC or PSM. Thus, rectangle or square coding windows can be formed to precisely expose the entire channel regions predetermined to.

Furthermore, the Mask ROM coding process described above is just one preferred embodiment of this invention and is not intended to restrict the scope of this invention. The photolithography process of this invention can also be applied to other semiconductor manufacturing processes to form openings.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

1. A photolithography process for Mask ROM coding, comprising: providing a substrate having an array of memory cells thereon; forming a first photoresist layer on the substrate covering the memory cells; performing a first exposure and development process to pattern the first photoresist layer into first line/space patterns; forming a second photoresist layer on the substrate covering the first line/space patterns; and performing a second exposure and development process to pattern the second photoresist layer into second line/space patterns having an orientation different from an orientation of the first line/space patterns, while a plurality of coding windows are defined by the first line/space patterns and the second line/space patterns.

2. The photolithography process of claim 1, wherein the first photoresist layer comprises a negative photoresist layer and the second photoresist layer comprises a positive photoresist layer.

3. The photolithography process of claim 1, wherein the orientation of the first line/space patterns is perpendicular to the orientation of the second line/space patterns.

4. The photolithography process of claim 1, wherein the first line/space patterns include a plurality of trenches having different lengths.

5. The photolithography process of claim 1, wherein the second line/space patterns comprise a plurality of linear patterns and linear spaces that are arranged regularly.

6. The photolithography process of claim 1, wherein the first exposure process and the second exposure process use off-axis illumination.

7. The photolithography process of claim 1, wherein the first exposure process and the second exposure process use an exposure light of 248 nm.

8. The photolithography process of claim 1, wherein a coding window defined by the first line/space patterns and the second line/space patterns has a square shape.

9. The photolithography process of claim 8, wherein the square-shaped coding window has dimensions of 0.12 μm×0.12 μm.

10. A photolithography process, comprising:forming a first photoresist layer on a substrate; performing a first exposure and development process to pattern the first photoresist layer into first line/space patterns; forming a second photoresist layer on the substrate covering the first line/space patterns; and performing a second exposure and development process to pattern the second photoresist layer into second line/space patterns having an orientation different from an orientation of the first line/space patterns, while a plurality of rectangle openings are defined by the first line/space patterns and the second line/space patterns.

11. The photolithography process of claim 10, wherein the first photoresist layer comprises a negative photoresist layer, and the second photoresist layer comprises a positive photoresist layer.

12. The photolithography process of claim 10, wherein the orientation of the first line/space patterns is perpendicular to an orientation of the second line/space patterns.

13. The photolithography process of claim 10, wherein the first line/space patterns include a plurality of trenches having different lengths.

14. The photolithography process of claim 10, wherein the second line/space patterns comprises a plurality of linear patterns and a plurality of linear spaces that are arranged regularly.

15. The photolithography process of claim 10, wherein a rectangle opening defined by the first line/space patterns and the second line/space patterns have a square shape.

16. The photolithography process of claim 10, further comprising performing a photoresist hardening process after the first photoresist layer is patterned into the first line/space patterns.

17. The photolithography process of claim 16, wherein the photoresist hardening process comprises implanting Ar or N₂ ions with a dosage from about 1×10¹⁴ to about 3×10¹⁵ /cm² and an implanting energy from about 2 KeV to about 50 KeV.

18. The photolithography process of claim 16, wherein the photoresist hardening process comprises a baking step at a temperature from about 100° C. to about 150° C. for a period from about 30 sec to about 180 sec.
